(19) United States
(12) Patent Application Publication
(10) Pub. No.: US 2011/0315201 A1
(43) Pub. Date: Dec. 29, 2011

(54) SOLAR CELL AND METHOD FOR FABRICATING THE HETEROJUNCTION THEREOF

(75) Inventors: CHING-FUH LIN, Taipei (TW); SHU-JIA SYU, Taipei (TW)

(73) Assignee: NATIONAL TAIWAN UNIVERSITY, Taipei (TW)

(21) Appl. No.: 12/975,933

(22) Filed: Dec. 22, 2010

(30) Foreign Application Priority Data
Jun. 25, 2010 (TW) 099120910

(51) Int. Cl. H01L 31/06; H01L 31/0352; B82Y 40/00

(52) U.S. Cl. 136/255; 438/92; 257/E31.037; 977/700

(57) ABSTRACT

Embodiments of the present invention provide methods to fabricate semiconductor nanostructure/polymer heterojunctions of solar cells. The methods comprise that a conductive polymer is adhered on the surface of semiconductor nanostructures by capillary effect and core-sheath shaped heterojunctions are formed. The incident photo-to-current conversion efficiency (IPCE) of the solar cells having core-sheath heterojunctions can reach 30% or more.

### CROSS-REFERENCE TO RELATED APPLICATIONS

The entire contents of Taiwan Patent Application No. 099120910, filed on Jun. 25, 2010, from which this application claims priority, are incorporated herein by reference.

### BACKGROUND OF THE INVENTION

1. Field of the Invention

The present invention generally relates to high efficiency solar cells and methods for fabricating their heterojunctions.

2. Description of Related Art

In the field of solar cell, the polymer/semiconductor heterojunction attracts lots of attention due to several advantages including free concern of lattice mismatch, large-area coverage, low-temperature process-capability, easy preparation, low cost, and so on. To date, researchers have demonstrated planar polymer/semiconductor heterojunction solar cells based on crystalline or amorphous silicon such as Poly-(CH₃)₃Si-Cyclooctatetraene/n-Si, tetraphenylporphyrin/n-Si, 4-tricyanovinyl-N,N-diethylaniline/p-Si, poly(3-hexylthiophene)/a-Si, poly(3,4-ethylenedioxy thiophene): poly(styrenesulfonate)/n-Si, polyaniline/n-Si, and phthalocyanine/n-Si, etc. However, with a planar polymer/silicon heterojunction, only the photogenerated electron-hole pairs (EHPs) near the junction will be separated and collected into electrical contacts. Other photogenerated EHPs produced in the polymer and the silicon will be mostly lost as a result of recombination. This limits the power conversion efficiency (PCE) of the polymer/silicon heterojunction solar cells.

To augment the EHPs separating and collecting, silicon nanowire (SiNW) structures are used in solar cells to enormously increase the p-n junction area and shorten the carrier diffusion distance. In addition, the nanowire structure significantly reduces the reflection and induces strong light trapping between nanowires, resulting in strong absorption. Mostly, to form SiNW p-n junction structures, a thin amorphous or nanocrystal silicon layer was deposited on the SiNW surface by chemical vapor deposition. The solar cells having so produced heterojunction show a spectrally broad incident photo-to-current conversion efficiency (IPCE) in the visible region but low IPCE in the near infrared region. High series and low shunt resistances appear to limit the power conversion efficiency (PCE) of these cells to below 1%.

Therefore, it would be advantageous to provide solar cells and their producing methods for promoting the incident photo-to-current conversion efficiency (IPCE).

### SUMMARY OF THE INVENTION

An object of this invention is to provide solar cells and method for producing their heterojunctions, as well as promoting the incident photo-to-current conversion efficiency (IPCE), and reducing the material and fabricating cost.

Accordingly, one embodiment of this invention provides a method for fabricating heterojunctions of a solar cell, comprising: providing a semiconductor substrate; forming a plurality of semiconductor nanostructures on the semiconductor substrate; and adhering a conducting polymer on each semiconductor nanostructure by capillary effect, and thus forming a plurality of semiconductor nanostructure/conducting polymer heterojunctions. The heterojunctions are employed to produce a solar cell.

Accordingly, one embodiment of this invention provides a solar cell, at least comprising a plurality of heterojunctions, wherein each heterojunction comprises a semiconductor nanostructure and a conducting polymer in a form of core-sheath, and the maximum incident photo-to-current conversion efficiency (IPCE) of the solar cell is equal to or more than 30%.

In an embodiment, the hole-conducting polymer poly(3,4-ethylenedioxythiophene):poly(styrenesulfonate) (PEDOT:PSS) is coated on the silicon nanowires (SiNWs) to replace the conventional p-doped amorphous or nanocrystal silicon layer and thus form a solar cell having SiNW/PEDOT heterojunctions. The highest occupied molecular orbital (HOMO) energy of PEDOT is about 5.1 eV, which is similar to the valence band energy of silicon. Thus, the interface between the PEDOT layer and n-type SiNWs could possibly form good heterojunctions for electron-hole pairs (EHPs) separation.

According to the embodiment, the current-to-voltage (J-V) characteristics of the SiNW/PEDOT solar cell clearly reveal a stable rectifying diode behavior. In addition, the heterojunctions can greatly increase the exciton dissociation probability and induce light trapping effect, leading to enhanced IPCE in the near infrared region. The power conversion efficiency (PCE) is also greatly improved as compared with the solar cells without nanowire/polymer heterojunctions.

According to an embodiment of this invention, a same semiconductor substrate can be repeatedly used to form nanostructures, greatly reducing the material cost. In addition, the fabricating steps may preferably use solution process to reduce the fabricating cost.

### BRIEF DESCRIPTION OF THE DRAWINGS

FIG. 1 shows a schematic diagram describing the procedures for fabricating a SiNW/PEDOT core-sheath heterojunction solar cell, according to an embodiment of this invention.

FIGS. 2(a)-2(d) show the scanning electron microscopy (SEM) images and transmission electron microscopy (TEM) images of the SiNWs array and the SiNW/PEDOT heterojunctions made by the embodiment shown in FIG. 1.

FIG. 3 shows the photovoltaic J-V characteristic of the SiNW/PEDOT solar cell fabricated by an embodiment of this invention, and comparison with a planar solar cell without SiNWs.

FIG. 4 shows a measured 2-D photocurrent mapping of the SiNW/PEDOT heterojunction solar cell fabricated by an embodiment of this invention.

FIG. 5(a) and FIG. 5(b) respectively show the IPCE and IPCE enhancement ratio spectrum of the SiNW/PEDOT solar cell fabricated by an embodiment of this invention.

FIGS. 6A-6G show a method for fabricating a solar cell having heterojunctions, according to another embodiment of this invention.

FIGS. 7A-7F show a method for fabricating a solar cell having heterojunctions, according to another embodiment of this invention.

### DESCRIPTION OF THE PREFERRED EMBODIMENT

Reference will now be made in detail to specific embodiments of the invention. Examples of these embodiments are illustrated in accompanying drawings. While the invention will be described in conjunction with these specific embodiments, it will be understood that it is not intended to limit the invention to these embodiments. On the contrary, it is intended to cover alternatives, modifications, and equivalents as may be included within the spirit and scope of the invention as defined by the appended claims. In the following description, numerous specific details are set forth in order to provide a thorough understanding of the present invention. The present invention may be practiced without some or all of these specific details. In other instances, well-known process operations and components are not described in detail in order not to unnecessarily obscure the present invention. While drawings are illustrated in detail, it is appreciated that the quantity of the disclosed components may be greater or less than that disclosed, except where expressly restricting the amount of the components. Wherever possible, the same or similar reference numbers are used in drawings and the description to refer to the same or like parts.

### Example to Fabricate Silicon Nanowires (SiNWs)

This example employs a metal-assisted chemical etching method (an electroless etching method) to produce silicon nanowires (SiNWs). Detail of the metal-assisted chemical etching method is described in U.S. application Ser. No. 12/713,094, entitled “Silicon substrate having nanostructures and method for producing the same and application thereof,” the entire contents of which are incorporated herein by reference.

First, an n-type 1-10 ohm-cm Si (100) wafer is provided to produce a SiNWs array in an aqueous solution of silver nitrate (AgNO₃) and hydrofluoric acid (HF) at room temperature. The concentrations of AgNO₃ and HF in solution are 0.023 and 5.6 molL⁻¹, respectively. After etching, the SiNWs array is immersed in a bath containing concentrated nitric acid to remove all Ag dendritic structures from the nanowire surfaces. Finally, the SiNWs array is immersed in a buffer oxidation etchant (BOE) to remove the oxide layer on the SiNWs and form H-terminated bonds (hydrogen bonds) on the silicon surface. The SiNWs array prepared by this method is aligned vertically over the area up to the wafer size, and its density may be equal to or more than 20 wires/μm², i.e., there are equal to or more than 20 silicon nanowires (or pieces) distributed per square of micrometer. Further, an aluminum layer is evaporated on the back side (the side without SiNWs) of the silicon substrate as the electrical contact. Besides, silicon nanowires could also be produced by a dry etching method.

### Example to Fabricate a Solar Cell

In this example, poly(3,4-ethylenedioxythiophene): poly(styrenesulfonate), referred to as “PEDOT” or “PEDOT:PSS” in this text, is used to form a SiNW/PEDOT heterojunctions solar cell.

After the SiNWs array is formed in the foregoing example, take PEDOT gel particles with a mean diameter of 80 nm to disperse it in water, and a PEDOT aqueous solution is formed. Because the surface of SiNWs with H-terminated bonds is hydrophobic after being immersed in the buffer oxidation etchant (BOE), it should be modified to hydrophilic, such that PEDOT can adhere to the SiNW surface and form SiNW/PEDOT heterojunction structures. To form a hydrophilic surface, the SiNWs array is placed in an environment with controlled relative humility of 60% and temperature of 25° C. for 2 hours, to form a very thin native oxide layer on the SiNW surface. By doing so, the thin native oxide layer is hydrophilic and has a contact angle below 20°. Then, instead of being directly spin-coated on the SiNWs array, the PEDOT aqueous solution is spin-coated on the ITO-coated glass and form a wet PEDOT film on it. The thickness of the wet PEDOT film is about 9 μm (the thickness of the dry PEDOT film is about 200 nm). Before the PEDOT film dried, the top portion of the SiNWs array is immersed in the wet PEDOT thin film.

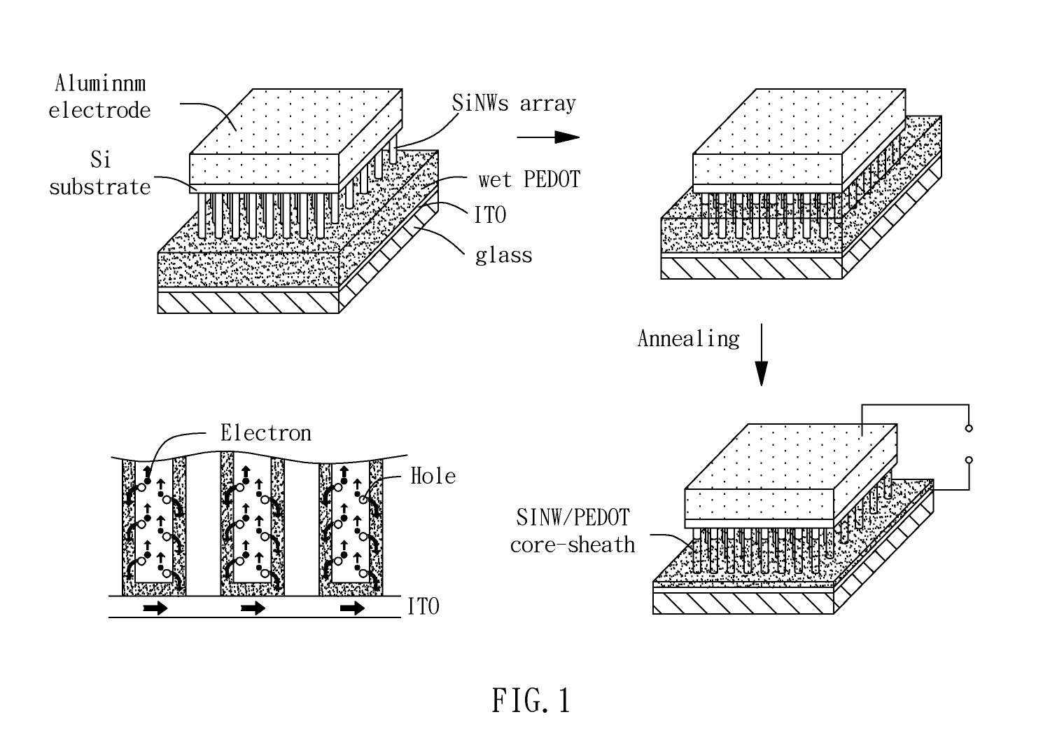

FIG. 1 shows a schematic diagram describing the procedures for fabricating a SiNW/PEDOT core-sheath heterojunction solar cell. The SiNWs fabricated by the metal-assisted chemical etching method are vertically aligned, highly dense, and very uniform in length. Therefore, when the top portion of the SiNWs array is being immersed in the wet PEDOT thin film, almost the whole SiNWs can be immersed into the wet PEDOT film via the capillary effect. Afterwards, the whole sample is annealed at 140° C. for 10 minutes in an N₂ environment. The wet PEDOT film is dried and form a compact PEDOT film on the SiNWs surface. Then, each individual SiNW is stuck on an ITO electrode via PEDOT and thus a SiNW/PEDOT heterojunction solar cell is formed. Notice that the capillary effect is carried out in room temperature in this example, but it can be done in other temperatures or other controlled parameters such as different PEDOT solution concentrations. Further, this solution process gives solar cells a cost benefit in comparison with the use of chemical vapor deposition.

### Result

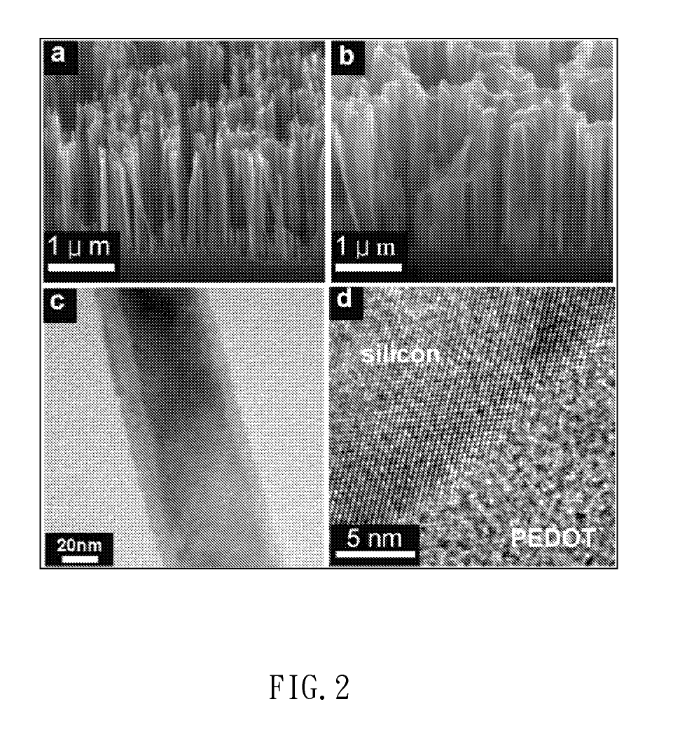

FIGS. 2(a)-2(d) show the scanning electron microscopy (SEM) images and transmission electron microscopy (TEM) images of the SiNWs array and the SiNW/PEDOT heterojunctions made by the foregoing example.

Where, FIG. 2(a) shows the SEM side view of the as-etched SiNWs, which are vertically aligned on the silicon substrate. FIG. 2(b) shows the SEM side view of the SiNWs detached from ITO coated glass by a mechanical force, and the SiNWs detached from ITO coated glass reveals that the PEDOT layer is covered on the SiNWs. To further investigate the SiNW/PEDOT heterojunction structures, FIG. 2(c) shows the TEM image of a single SiNW detached from ITO coated glass; the image shows that it is a core-sheath structure. The single crystalline silicon core is aligned to a zone axis, leading to much stronger diffraction and thus darker contrast compared to the PEDOT sheath. The thickness of the PEDOT is below 20 nm. This image confirms that the PEDOT covers the whole surface of the SiNWs rather than just the top of the SiNWs. FIG. 2(d) shows the high-resolution TEM image taken near the edge of the SiNW in which the PEDOT is compactly adhered on the SiNW surface.

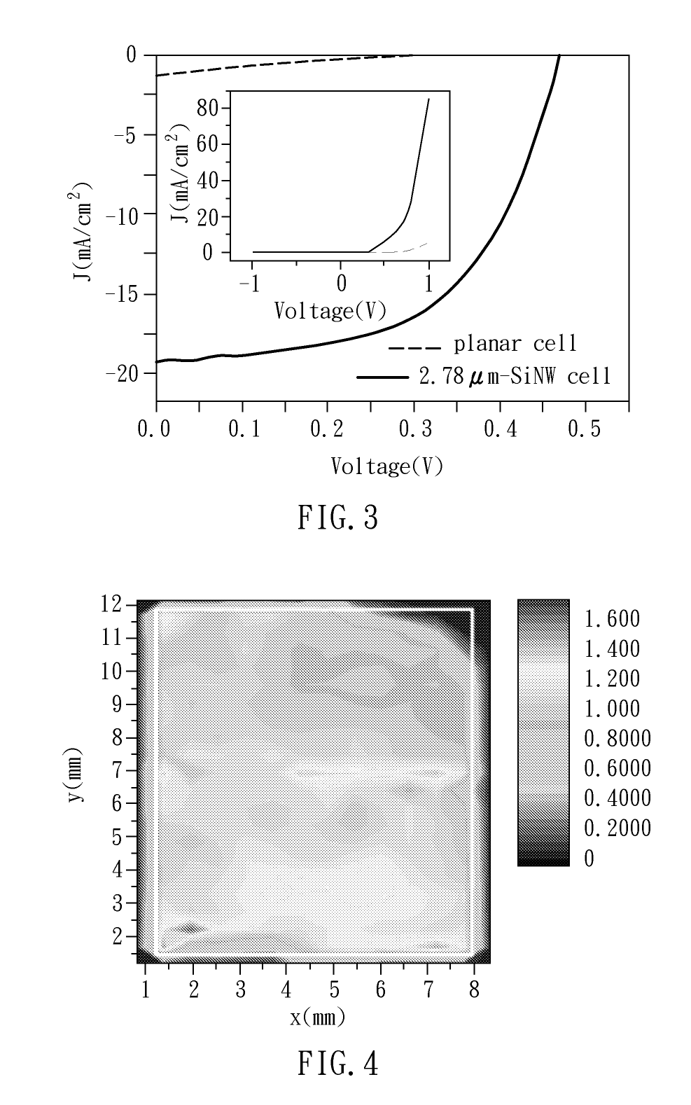

FIG. 3 shows the photovoltaic J-V characteristic of the SiNW/PEDOT solar cell fabricated by the foregoing example of this invention, and comparison with a planar solar cell without SiNWs (a planar Si/PEDOT heterojunction solar cell). The photovoltaic J-V characteristic is measured under an illumination intensity of 100 mW/cm² (AM1.5 G). Further, the inset shows the dark current-voltage characteristics of the SiNW/PEDOT solar cell. A strong increase in short-circuit current density (Jsc), open-circuit voltage (Voc), fill factor (FF), and power conversion efficiency (PCE) is observed in the SiNW/PEDOT solar cell with 2.78-μm SiNW structures, as compared with the planar cell without nanowires. The Jsc is improved from 1.27 mA/cm² to 19.28 mA/cm², the Voc from 0.34 V to 0.47 V, and the FF from 18% to 61%, resulting in an improvement of the power conversion efficiency (PCE) from 0.08% to 5.09%.

The increase of the short-circuit current density (Jsc) is due to two major reasons. First, the diffusion distance of carriers from the core of SiNW to SiNW/PEDOT heterojunction is only tens of nanometers or below. In contrast, the distance may be several micrometers for the planar solar cell. Thus, the electron-hole pairs (EHP) separation and collection efficiency is greatly enhanced in the SiNW/PEDOT solar cell. Second, the reflectance of the SiNW arrays reduces to below 5% over the spectral range of 400-1100 nm as compared with the planar silicon surface having reflectance over 30%. In addition, light trapping by the SiNW arrays increases the light absorption of SiNWs. These lead to the enhancement of photocurrent.

In the inset of FIG. 3, the dark current density at a forward bias also is enhanced in the SiNW/PEDOT cell, as compared with the planar solar cell. The measured current-to-voltage (J-V) characteristics of the SiNW/PEDOT cells clearly reveal a stable rectifying diode behavior. The series resistance is 60.42 Ωcm² for the planar cell, and 1.47 Ωcm² for the SiNW/PEDOT device. The improvement in the fill factor for the SiNW/PEDOT cells could be attributed to this general reduction in the series resistance. The result indicates that the SiNW structure increases the heterojunction area and thus greatly enhances current density. The series resistance of the SiNW/PEDOT heterojunction cells is even lower than that of SiNW homojunction cells reported in the literatures. The reason is that, in the architecture of the SiNW/PEDOT solar cells, the charge carriers can be directly transported between the SiNW and the planar ITO electrode through PEDOT. Therefore, the reduction of the series resistance due to the increase in the junction area is observed.

FIG. 4 shows a measured 2-D photocurrent mapping of the SiNW/PEDOT heterojunction solar cell fabricated by the foregoing example of this invention. The uniformity of the SiNW/PEDOT heterojunction and the contact of the SiNWs on the ITO surface are investigated. The white frame in FIG. 4 indicates the active region of the SiNW/PEDOT solar cell. The results show that the photocurrent map has a uniform response within the active region. This means that most photogenerated electron-hole pairs (EHPs) in the SiNWs can be separated and collected in the electrical contacts. The holes are collected in the ITO film and the electrons are collected in the aluminum contact. This experiment also indicates that most SiNWs can be stuck on the ITO electrode via PEDOT.

The architecture of the SiNW/PEDOT solar cell takes advantage of charge carrier transport in the nanowire structures. In the foregoing example of this invention, a planar ITO thin film is used to contact the top of the SiNWs via PEDOT as the front contact(s) instead of conventional metal fingers. In conventional planar solar cells, charge carriers in the emitter will transport near the front surface to the metal fingers. Therefore, if the front surface of the solar cells forms nanostructures, the charge carriers in the emitter will transport a much longer distance than that in the planar solar cells. This may increase the series resistance. The SiNW/PEDOT solar cell architecture proposed by the foregoing example means that the charge carriers separated in the SiNWs could be immediately collected to the ITO electrode instead of diffusing a long distance through SiNW arrays as shown in FIG. 1. It could lower the series resistance of SiNW solar cells.

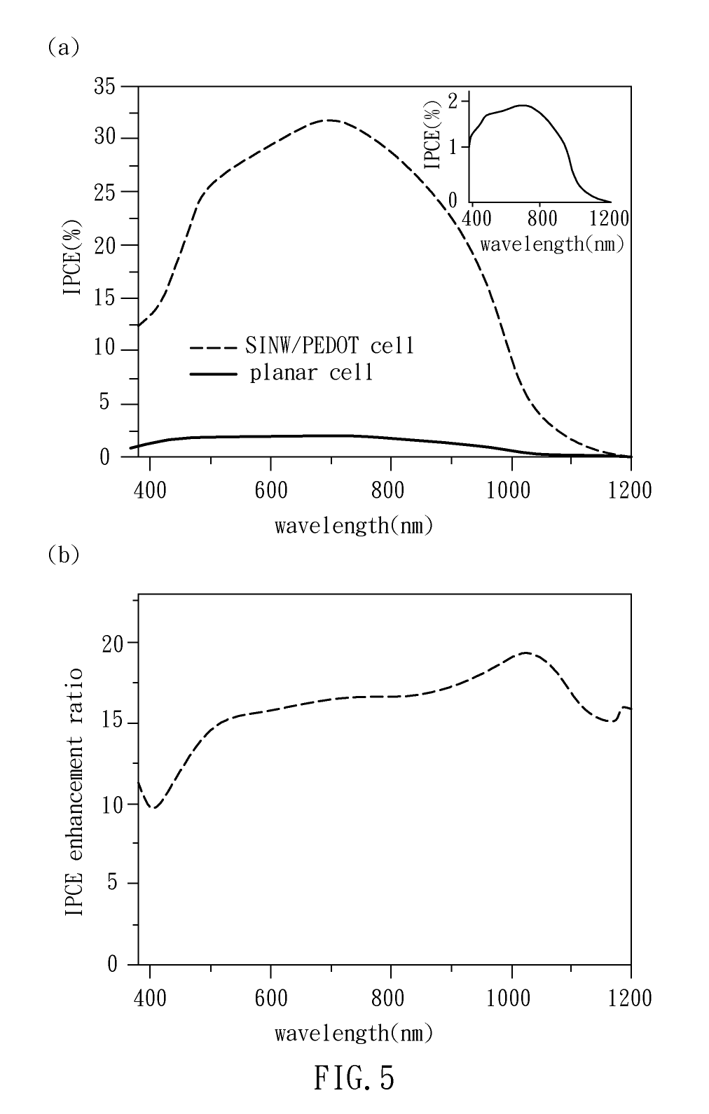

FIG. 5(a) and FIG. 5(b) respectively show the IPCE and IPCE enhancement ratio spectrum of the SiNW/PEDOT solar cell fabricated by the foregoing example of this invention. Further, FIG. 5(a) and the inset in FIG. 5(a) shows the IPCE of the planar Si/PEDOT solar cell for investigating the reasons improving the efficiency.

The SiNW/PEDOT solar cell harvests photons from 400 nm to 1100 nm, and gives a maximum IPCE of 32% at 700 nm. In contrast, for planar cell, the maximum IPCE is only about 1.94% occurring at 682 nm, as shown in the inset of FIG. 5(a). For the SiNW/PEDOT solar cell, the IPCE enhancement ratio is over 15 from 530 nm to 1100 nm as shown in FIG. 5(b). This ratio achieves a maximum value at the wavelength of 1014 nm. The phenomenon of the enhanced IPCE in the SiNW/PEDOT cell can be attributed to the light trapping effect. For the planar cell, the light penetrating in the silicon substrate reaches several micrometers in depth for the visible region, and several tens of micrometers for the near-infrared (NIR) region. The poor carrier collection efficiency in the deep region of the silicon substrate causes low photocurrent and low IPCE, especially in the near-infrared (NIR) region. However, for the SiNW/PEDOT cell, the strong light trapping effect in the SiNW structure increases the optical absorption from the visible region to the NIR region. Furthermore, the core-sheath structure facilitates efficient EHP separation and collection in the radial directions of nanowires. Thus, the IPCE can be greatly enhanced.

A person skilled in the art recognizes that modifications and alternatives may be made in the foregoing examples of this invention. Another embodiment of this invention provides a method of producing a solar cell with heterojunctions. The method comprises the steps of: (1) provide a semiconductor substrate; (2) form a plurality of semiconductor nanostructures on the semiconductor substrate; (3) adhere a conducting polymer on each semiconductor nanostructure by capillary effect, and thus form a plurality of semiconductor nanostructure/conducting polymer heterojunctions; and (4) employ the semiconductor nanostructure/conducting polymer heterojunctions to produce a solar cell.

The above-mentioned semiconductor nanostructures may include silicon nanowires, germanium nanowires, III-V compound nanowires, II-VI compound nanowires, and so on. The foregoing metal-assisted chemical etching method may be employed to etch the semiconductor substrate and thus form the semiconductor nanostructures. Alternatively, other known vapor-phase epitaxy or liquid-phase epitaxy methods may be used to produce the semiconductor nanostructures. The conducting polymer may include [poly(3,4-ethylenedioxy thiophene): poly(styrene sulfonate)]; (PEDOT:PSS), (Poly(3-hexylthiophene); P3HT), (6,6-phenyl-C61-butyric acid methyl ester; PCBM), polyaniline, phthalocyanine, Poly-(CH₃)₃Si-Cyclooctatetraene, tetraphenylporphyrin, 4-tricyanovinyl-N,N-diethylaniline, and the like.

In addition, method to adhere the conducting polymer to the semiconductor nanostructures is exemplarily summarized as follows. First, dissolve the conducting polymer in a solvent that is water or an organic solvent, forming a conducting polymer solution. If the solvent is the organic solvent such as acetone, methanol, or isopropanol, then modify the surface of the semiconductor nanostructures to be hydrophobic; if the solvent is water, then modify the surface of the semiconductor nanostructures to be hydrophilic. Then, the top portions of the semiconductor nanostructures are inserted into the conducting polymer solution, which then adhere to the surface of the semiconductor nanostructures by capillary effect. For example, the conducting polymer solution is coated on a transparent conducting substrate or a transparent electrode of a transparent substrate, and then the top portions of the semiconductor nanostructure are inserted into the conducting polymer solution, which is wet and moveable at that time. Afterward, heat the conducting polymer solution to make it solid, and thus the conductivity of which is promoted.

The foregoing transparent conducting substrate or transparent electrode may comprise indium tin oxide (ITO), and the transparent substrate may be glass substrate, plastic substrate, quartz substrate, and so on. Further, spin coating or dip coating method may be employed for coating the conducting polymer solution on the transparent conducting substrate or the transparent electrode.

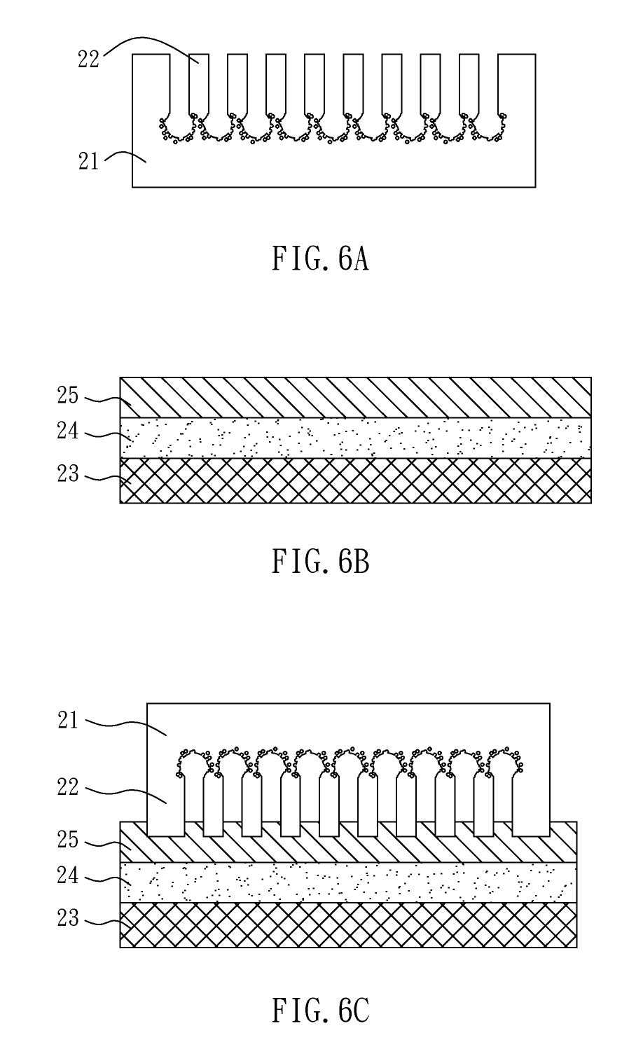

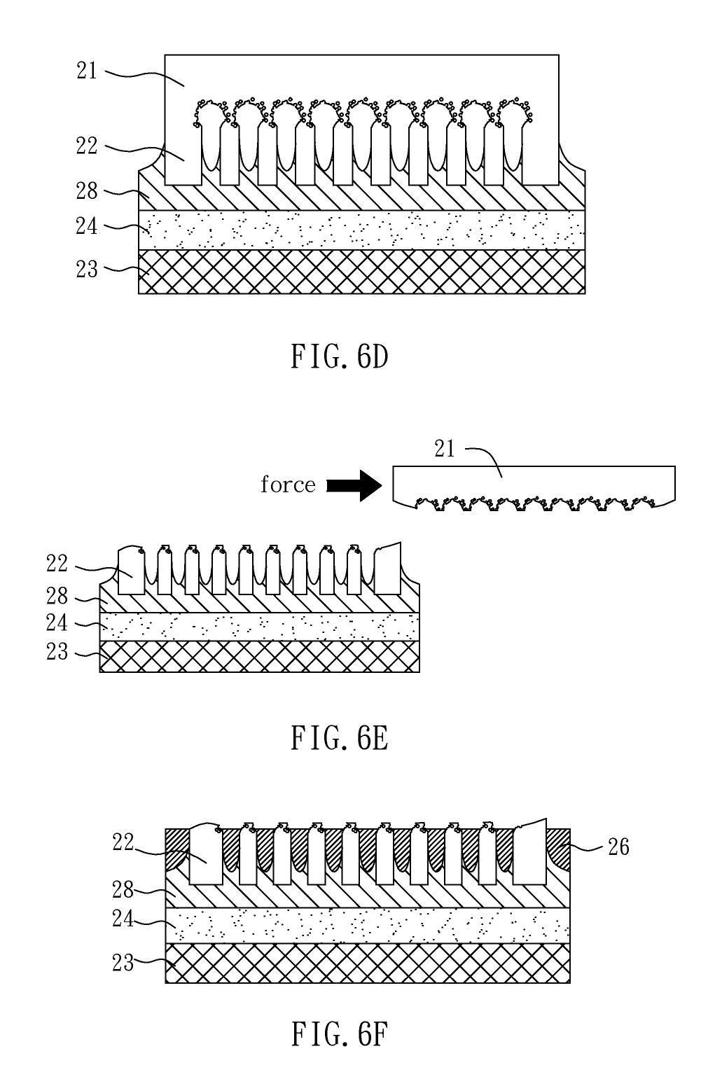

FIGS. 6A-6G show a method for fabricating a solar cell having heterojunctions, according to another embodiment of this invention. Notice that the modifications and alternatives of the forgoing examples may be made in this example. First, referring to FIG. 6A, a plurality of semiconductor nanostructures 22 whose root portion is side-etched and porous are formed on a semiconductor substrate 21. In this example, the semiconductor nanostructures 22 are formed by a metal-assisted chemical side-etching method, which is described in U.S. application Ser. No. 12/790,331, filed May 28, 2010, and entitled “Silicon nanostructures and method for producing the same and application thereof,” the entire contents of which are incorporated herein by reference. Referring to FIG. 6B, a conducting polymer solution 25 is coated on a transparent electrode 24 of a transparent substrate 23. Referring to FIG. 6C, the top portions of the semiconductor nanostructures 22 are inserted into the conducting polymer solution 25 under a condition that the solution 25 is wet and moveable. Referring to FIG. 6D, after the conducting polymer solution 25 is adhered to the surface of the semiconductor nanostructures 22 by capillary effect, the conducting polymer solution 25 is heated to solidify it to a conducting polymer 28. Referring to FIG. 6E, a mechanical force is exerted to make the semiconductor nanostructures 22 from the semiconductor substrate 21. Referring to FIG. 6F, an insulating layer 26 is formed to cover the conducting polymer 28 but expose the semiconductor nanostructures 22. Referring to FIG. 6G, a metal electrode 27 is formed to cover the insulating layer 26 and the semiconductor nanostructures 22.

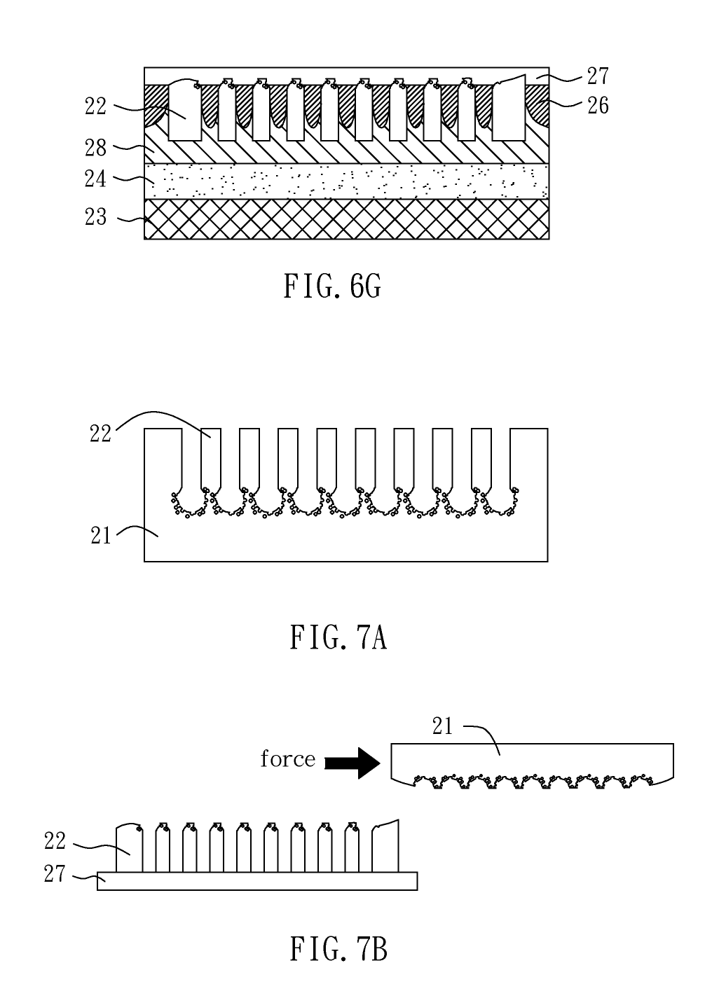

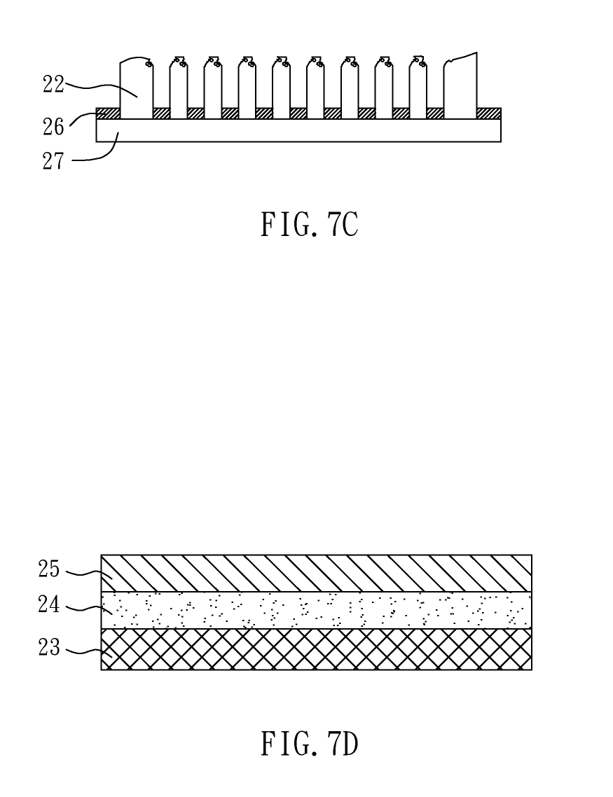

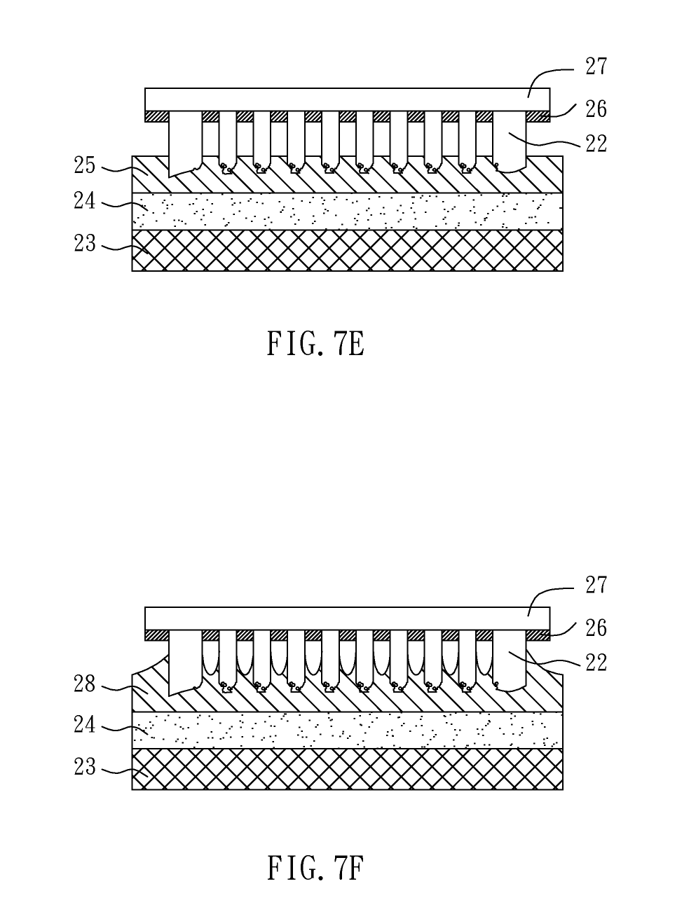

FIGS. 7A-7F show a method for fabricating a solar cell having heterojunctions, according to another embodiment of this invention. Notice that this example is different from the example shown in FIGS. 6A-6G in the order of the steps; the same reference numbers are therefore employed in this example. Referring to FIG. 7A, a plurality of semiconductor nanostructures 22 whose root portion is side-etched and porous are formed on a semiconductor substrate 21. Referring to FIG. 7B, the semiconductor nanostructures 22 are detached form the semiconductor substrate 21 and removed to a metal electrode 27. For example, the semiconductor nanostructures 22 are firstly fixed on the metal electrode 27, and then exert a mechanical force to detach it from the semiconductor substrate 21. Referring to FIG. 7C, an insulating layer 26 is formed to cover the metal electrode 27 but expose the semiconductor nanostructures 22. Referring to FIG. 7D, a conducting polymer solution 25 is coated on a transparent electrode 24 of a transparent substrate 23. Referring to FIG. 7E, the top portions of the semiconductor nanostructures 22 are inserted into the conducting polymer solution 25 under a condition that the solution 25 is wet and moveable. Referring to FIG. 7F, after the conducting polymer solution 25 is adhered to the surface of the semiconductor nanostructures 22 by capillary effect, the conducting polymer solution 25 is heated to solidify it to a conducting polymer 28.

According to embodiments of this invention, the diffusion distance of charge carriers is significantly reduced, reducing the probability of lattice colliding with the carriers and thus increasing the hot carrier effect. Therefore, the output voltage, i.e., the open circuit voltage (Voc), of the semiconductor nanostructure/conducting polymer heterojunctions solar cell will be higher than planar cells, and gives a maximum IPCE of 32% at 700 nm. In addition, if the semiconductor nanostructures are detached from the semiconductor substrate by further employing the side-etching and transferring method described above and then employ it to produce a solar cell, not only the material cost but also the thickness of light absorbing layer can be greatly reduced. In addition to employ the above advantageous processes, an embodiment of this invention made a hot carrier solar cell having a maximum IPCE equal to or more than 40% or 50%, by further properly selecting the difference between the work function of the two electrical contacts (electrodes) and cooperating with other suitable materials.

Although specific embodiments have been illustrated and described, it will be appreciated by those skilled in the art that various modifications may be made without departing from the scope of the present invention, which is intended to be limited solely by the appended claims.

What is claimed is:

1. A method for fabricating heterojunctions of a solar cell, comprising:
providing a semiconductor substrate;
forming a plurality of semiconductor nanostructures on the semiconductor substrate; and
adhering a conducting polymer on each semiconductor nanostructure by capillary effect, and thus forming a plurality of semiconductor nanostructure/conducting polymer heterojunctions.

2. The method as recited in claim 1, wherein the semiconductor nanostructures comprise silicon nanowires, germanium nanowires, III-V compound nanowires, or II-VI compound nanowires.

3. The method as recited in claim 1, wherein a metal-assisted chemical etching method or a dry etching method is employed to etch the semiconductor substrate and thus form the semiconductor nanostructures, and the density of the semiconductor nanostructures is equal to or more than 20 pieces/μm².

4. The method as recited in claim 1, wherein the step for producing the semiconductor nanostructures comprises a vapor-phase epitaxy method or a liquid-phase epitaxy method.

5. The method as recited in claim 1, wherein the conducting polymer is selected from the group consisting of poly(3,4-ethylenedioxy thiophene): poly(styrene sulfonate), poly(3-hexylthiophene), polyaniline, phthalocyanine, Poly-(CH₃)₃Si-Cyclooctatetraene, tetraphenylporphyrin, 4-tricyanovinyl-N,N-diethylaniline and 6,6-phenyl-C61-butyric acid methyl ester.

6. The method as recited in claim 1, wherein the step to adhere the conducting polymer to the semiconductor nanostructures by capillary effect comprises:
dissolving the conducting polymer in a solvent, thus forming a conducting polymer solution;
modifying the surface of the semiconductor nanostructures to be hydrophilic or hydrophobic, according to the character of the solvent;
inserting the top portions of the semiconductor nanostructures into the conducting polymer solution, which then adhere to the surface of the semiconductor nanostructures by capillary effect; and
heating the conducting polymer solution to dry the conducting polymer solution.

7. The method as recited in claim 6, wherein the solvent is an organic solvent, and the surface of the semiconductor nanostructures is modified to be hydrophobic.

8. The method as recited in claim 7, wherein the organic solvent comprises acetone, methanol, or isopropanol.

9. The method as recited in claim 6, wherein the solvent is water, and the surface of the semiconductor nanostructures is modified to be hydrophilic.

10. The method as recited in claim 6, wherein the conducting polymer solution is firstly coated on a transparent conducting substrate or a transparent electrode of a transparent substrate, and then the top portions of the semiconductor nanostructure are inserted into the conducting polymer solution, under a condition that the conducting polymer solution is wet and moveable.

11. The method as recited in claim 10, wherein the conducting polymer solution is coated on the transparent conducting substrate or the transparent electrode of the transparent substrate via a spin coating method or a dip coating method.

12. The method as recited in claim 10, wherein the transparent conducting substrate or the transparent electrode comprises indium tin oxide (ITO).

13. The method as recited in claim 10, wherein the transparent substrate comprises glass substrate, plastic substrate, or quartz substrate.

14. The method as recited in claim 10, wherein a metal-assisted chemical side-etching method is used for side-etching the root portion of each semiconductor nanostructure, before the step of adhering the conducting polymer.

15. The method as recited in claim 14, wherein after the plurality of semiconductor nanostructure/conducting polymer heterojunctions are formed, further comprises the steps of:
exerting a mechanical force to detach the semiconductor nanostructures from the semiconductor substrate;
forming an insulating layer to cover the conducting polymer but expose the semiconductor nanostructures; and
forming a metal electrode to cover the insulating layer and the semiconductor nanostructures.

16. The method as recited in claim 14, wherein before the plurality of semiconductor nanostructure/conducting polymer heterojunctions are formed, further comprises the steps of:
transferring the semiconductor nanostructures on metal electrode in a physically manner; and
forming an insulating layer to cover the metal electrode but expose the semiconductor nanostructures.

17. The method as recited in claim 1, wherein the maximum incident photo-to-current conversion efficiency (IPCE) of the solar cell is equal to or more than 30%.

18. The method as recited in claim 1, wherein the solar cell is a hot carrier solar cell.

19. A solar cell, at least comprising a plurality of heterojunctions, wherein each heterojunction comprises a semiconductor nanostructure and a conducting polymer in a form of core-sheath, and the maximum incident photo-to-current conversion efficiency (IPCE) of the solar cell is equal to or more than 30%.

20. The solar cell as recited in claim 19, wherein one end of the semiconductor nanostructure connects to a metal electrode, the other end of the semiconductor nanostructure connects to a transparent electrode via the conducting polymer, and an insulating layer is arranged between the metal electrode and the conducting polymer.

21. The solar cell as recited in claim 19, wherein the semiconductor nanostructures comprise silicon nanowires, germanium nanowires, III-V compound nanowires, or II-VI compound nanowires.

22. The solar cell as recited in claim 19, wherein the conducting polymer is selected from the group consisting of poly(3,4-ethylenedioxy thiophene): poly(styrene sulfonate), poly(3-hexylthiophene), and 6,6-phenyl-C61-butyric acid methyl ester.

23. The solar cell as recited in claim 19, wherein the density of the semiconductor nanostructures is equal to or more than 20 pieces/μm².

24. The solar cell as recited in claim 19, wherein the solar cell is a hot carrier solar cell.
